(19) United States
(12) Patent Application Publication
(10) Pub. No.: US 2008/0237884 A1
(43) Pub. Date: Oct. 2, 2008

(54) Packaging substrate structure

(75) Inventor: Shih-Ping Hsu, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/073,830

(22) Filed: Mar. 11, 2008

(30) Foreign Application Priority Data
Mar. 30, 2007 (TW) 096111207

(51) Int. Cl. H01L 23/48

(52) U.S. Cl. 257/774; 257/E23.01

(57) ABSTRACT

A packaging substrate structure is disclosed, which at least comprises a build-up structure including a first dielectric layer, a second dielectric layer and a third dielectric layer. The second dielectric layer is disposed between the first dielectric layer and the third dielectric layer. The characteristic is that the Young's modulus of the second dielectric layer is lower then the first dielectric layer and the third dielectric layer so as to form a sandwich structure of high-low-high of Young's modulus. The packaging substrate structure of the present invention can improve the quality of the product.

### BACKGROUND OF THE INVENTION

1. Field of the Invention

The present invention relates to a packing substrate structure, and, more particularly, to a packing substrate structure applied in mitigation of stress.

2. Description of Related Art

Customer demands of the electronics industry continue to evolve rapidly and the main trends are high integration and miniaturization. In order to satisfy those requirements, especially in the packaging of semiconductor devices, development of circuit boards with the maximum of active and passive components and conductive wires has progressed from single to multiple layer types. This means that a greater usable area is available due to interlayer connection technology.

In the conventional semiconductor device, semiconductor chips are mounted on top of a substrate, and then processed in wire bonding, or in flip chip to connect the chip having the solder bump thereon to the conductive pads on the substrate, followed by placing solder balls on the back of the substrate to provide electrical connections for outer electronic components such as printed circuit board. Compared with wire bonding, the flip chip is characterized in that conduction between the semiconductor chip and the circuit board is achieved by solder bumps, but not by common Au wires. Therefore, the density of layout circuits on the substrate and I/O numbers of the semiconductor chip mounted thereon can be promoted. Besides, as conductive wires are no longer necessary, conductive distance is thus decreased so as to promote conductive efficiency. Requirements for the semiconductor devices with high circuit density and high-speed responses can be satisfied.

Conventional packaging substrate structures are manufactured from a beginning of a core substrate, followed by drilling, plating metal in through holes, plugging holes, patterning circuits etc. to complete inner circuit structures. Subsequently, the multilayer carrier having a built-up structure thereon manufactured by the built-up technology is formed as shown in FIG. 1A. First, a core substrate 11, of which built-up structures 12 are respectively disposed on two sides, is provided. Beside, circuit layers on the two sides of the core substrate 11 are conducted together by a plated through hole 111. The built-up structures 12 respectively comprise a dielectric layer 121, an upper circuit layer 122 stacked on the dielectric layer 121, and conductive vias 123 stacked in the dielectric layer 121. Beside, plural conductive pads 124 are formed on the surface of the built-up structures 12, and a solder mask 12, having plural openings 131 located thereon to reveal the conductive pads 124, is formed on the outer surfaces of the built-up structure 12. Solder materials (not shown in FIG. 1) are formed in the openings 131 so as to conduct the packaging substrate to outer electronic components.

Generally, the dielectric layer 121 is made of a photosensitive or non-photosensitive material, such as Ajinomoto Build-up film (ABF), bismaleimide triazine (BT), benzocylobutene (BCB), liquid crystal polymer (LCP), polyimide (PI), poly(phenyl ether) (PPE), poly(tetrafluoroethylene) (PTFE), aramide, epoxy resin, resin containing rubber, and glass fiber, or a mixture of epoxy resin and glass fiber. The solder mask is made of green lacquer and so forth. Nevertheless, built-up structures contain at least three layers, which are formed on multilayer substrates with output/input in quantities, and stacked conductive via structures are often used therein. The dielectric layer 121 and the solder mask 13 are respectively made of a material having the Young's modulus or the elastic modulus greater than 3 Gpa. Besides, coefficient of thermal expansion (CTE) thereof is about 40 ppm/° C. while the temperature is lower than the glass transition temperature, and that is about 140 ppm/° C. while the temperature is greater than the glass transition temperature. Hygroscopicity thereof is greater than 1.0%. The material having the aforementioned properties can be applied in packing substrates due to meeting reliability standards and being adopted by clients.

However, the Young's modulus of the material of the dielectric layer is too great to be applied in a packaging substrate having I/O in quantities. That unsuitability causes unstable products due to mismatch of CTEs while chips are mounted on packaging substrates. Besides, the popcorn effect happens under reliability tests if the dielectric layer has too great hygroscopicity. With reference to FIG. 1B, in the multilayer packaging substrate having stacked conductive vias 123, interfaces between the conductive vias 123 are broken because the material of the dielectric layer has too great hygroscopicity and elastic modulus. Therefore, the quality of the products is reduced by aforementioned problems. In order to avoid cracks of the conductive vias 123, the upper portions of those vias need to be greater than or equal to 60 μm in diameter. Accordingly, neither can trends toward the conductive vias in smaller diameter be achieved, nor are packaging substrates having high circuit density manufactured.

### SUMMARY OF THE INVENTION

In view of the problems illustrated above, the present invention provides a packaging substrate structure which at least comprises a built-up structure comprising a first dielectric layer, a second dielectric layer, and a third dielectric layer, wherein the second dielectric layer is located between the first dielectric layer and the third dielectric layer, and the packaging substrate structure is characterized in that the Young's modulus of the second dielectric layer is lower than those of the first and third dielectric layers so as to form a sandwich structure having high-low-high Young's modulus.

In the packaging substrate structure of the present invention, the first and third dielectric layers respectively have a high Young's modulus. The Young's modulus of second dielectric layer is below 1 Gpa, preferably between 50 and 800 Mpa, more preferably between 50 and 500 Mpa. Furthermore, the first, second, and third dielectric layers can be made of materials having hygroscopicity below 1.0%, preferably below 0.8%, more preferably below 0.5%.

In the packaging substrate structure of the present invention, the built-up structure further comprises plural conductive vias formed in the dielectric layers (the first, second, and third dielectric layers) and circuit layers formed between the dielectric layers so as to conduct the circuit layer between the dielectric layers by the conductive vias.

In the packaging substrate structure of the present invention, the built-up structure is a multilayer structure having the second dielectric layer having low Young's modulus located between the first and third dielectric layers having high Young's modulus.

In the packaging substrate structure of the present invention, the built-up structure further comprises plural conductive pads and a solder mask. The conductive pads are formed on the surface of the built-up structure. The solder mask is formed on the surface of the built-up structure, on which plural openings are formed to reveal the conductive pads disposed on the surface of the built-up structure. Besides, the built-up structure can further comprise a solder material formed on the surfaces of the conductive pads so as to conduct outer electronic components. Herein, the outer electronic components are selected from the group consisting of passive components, active components, optoelectronic components, and circuit boards, but preferably are active components which especially are semiconductor chips. Moreover, the solder mask disposed on the built-up structure is preferably made of a photosensitive polymer material having a characteristic of dewetting.

In the present invention, the first dielectric layer, the second dielectric layer, and the third dielectric layer are respectively selected from a photosensitive or non-photosensitive material consisting of Ajinomoto Build-up film (ABF), bismaleimide triazine (BT), benzocylobutene (BCB), liquid crystal polymer (LCP), polyimide (PI), poly(phenyl ether) (PPE), poly(tetrafluoroethylene) (PTFE), aramide, epoxy resin, resin containing rubber, and glass fiber, or a mixture of epoxy resin and glass fiber.

Conclusively, in the packing substrate of the present invention, when the second dielectric layer is made of a material having the Young's modulus below 1 Gpa, the second dielectric layer can absorb stress resulting from different coefficients of thermal expansion. Because of the low Young's modulus of the second dielectric layer, the packing substrate will not experience warpage under tests of reliability. Besides, the interface of the conductive vias disposed in the built-up structure will not experience breakage so that an upper diameter of less than 60 μm of the conductive vias can be achieved. Hence, the packing substrate having fine circuits of high integration can be manufactured.

Other objects, advantages, and novel features of the invention will become more apparent from the following detailed description when taken in conjunction with the accompanying drawings.

### BRIEF DESCRIPTION OF THE DRAWINGS

FIG. 1A is a cross-sectional view of a conventional packing substrate structure;

FIG. 1B is an enlargement in a cross-sectional view of the conductive vias shown in FIG. 1A;

FIG. 2A is a cross-sectional view of a packing substrate structure in the present invention; and

FIG. 2B is an enlargement in a cross-sectional view of the built-up structure shown in FIG. 2A.

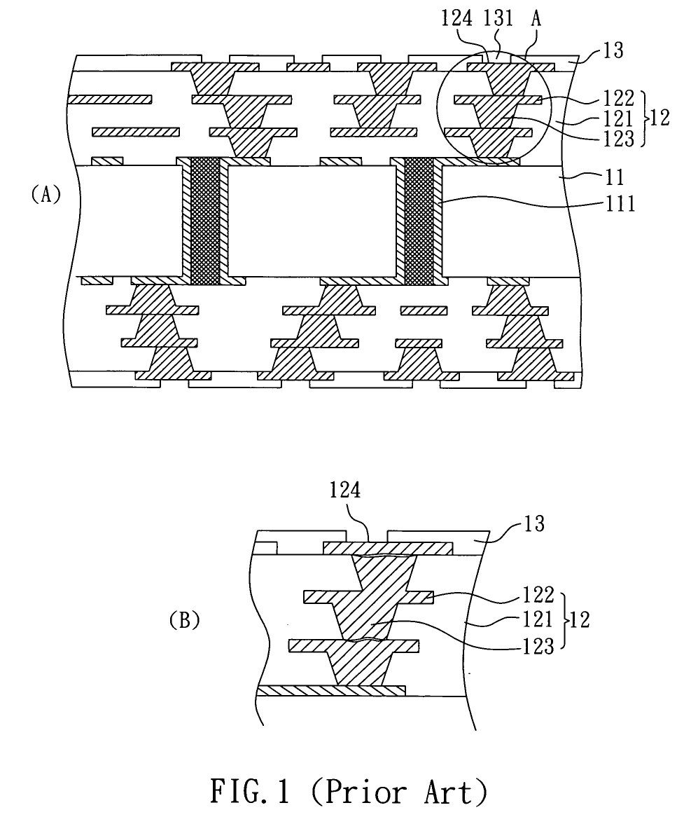

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The drawings of the embodiments in the present invention are all simplified charts or views, and only reveal elements relative to the present invention. The elements revealed in the drawings are not necessarily aspects of the practice, and quantity and shape thereof are optionally designed. Further, the design aspect of the elements can be more complex.

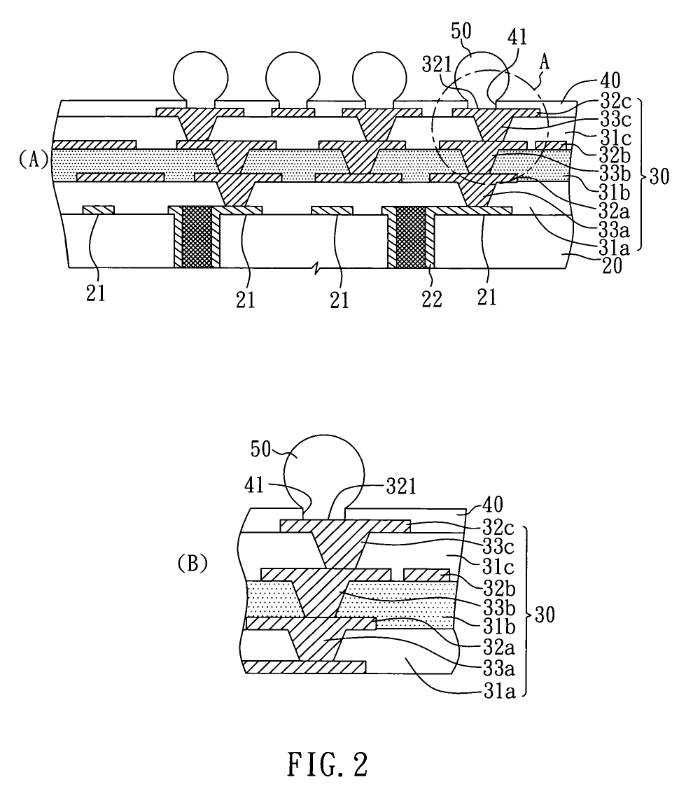

With reference to FIGS. 2A and 2B, FIG. 2A shows a packaging substrate structure of the present invention in a cross-sectional view, and FIG. 2B shows an enlarged view of a built-up structure in the packaging substrate. In the present embodiment for manufacturing a packaging substrate structure, a core board 20 is provided first. Through the built-up technology, a built-up structure 30 is formed on the surface of the core board 20, as shown in FIG. 2B. Herein, the core board 20 can be a circuit board completed with circuits. Besides, a circuit layer 21 is formed on the surface of the core board 20 in which plated through holes 22 are formed. The plated through holes 22 can conduct the circuit layer 21 respectively on two sides of the core board 20.

As shown in FIG. 2B, there is an enlargement view of the A area in FIG. 2A. The built-up structure 30 formed on the surface of the core board 20 at least comprises a first dielectric layer 31a, a second dielectric layer 31b, and a third dielectric layer 31c. The second dielectric layer 31b is located between the first dielectric layer 31a and the third dielectric layer 31c. Besides, the built-up structure 30 can further comprise circuit layers 32a, 32b, 32c respectively stacked on the first dielectric layer 31a, on the second dielectric layer 31b, and on the third dielectric layer 31c, and conductive vias 33a, 33b, 33c respectively conducting the circuit layers 32a, 32b, 32c to inner circuit layers. The circuit layer 32c on the third dielectric layer 31c in the built-up structure has plural conductive pads 321. Moreover, the first dielectric layer 31a, the second dielectric layer 31b, and the third dielectric layer 31c respectively are made of a photosensitive or non-photosensitive material, such as Ajinomoto Build-up film (ABF), bismaleimide triazine (BT), benzocylobutene (BCB), liquid crystal polymer (LCP), polyimide (PI), poly(phenyl ether) (PPE), poly(tetrafluoroethylene) (PTFE), aramide, epoxy resin, resin containing rubber, and glass fiber, or a mixture of epoxy resin and glass fiber. However, the first dielectric layer 31a and the third dielectric layer 31c are made of a material having high Young's modulus. The second dielectric layer 31b located between the first dielectric layer 31a and the third dielectric layer 31c in the built-up structure 30 of the present invention is made of a dielectric material having the Young's modulus below 1 Gpa.

As regards the circuit layers 32a, 32b, 32c respectively stacked on the first dielectric layer 31a, on the second dielectric layer 31b, and on the third dielectric layer 31c, and the conductive vias 33a, 33b, 33c respectively conducting the circuit layers 32a, 32b, 32c to inner circuit layers, materials thereof are preferably Cu. Interfaces between the conductive vias 33a, 33b, 33c and the circuit layers 32a, 32b, 32c on the first dielectric layer 31a, the second dielectric layer 31b, and the third dielectric layer 31c are not cracked because a sandwich structure formed by three dielectric layers having an arrangement of high-low-high Young's modulus can cushion stress so as to maintain the electrical quality of the packaging substrate.

The present invention is not limited in the structure of the second dielectric layer 31b located between two dielectric layers, i.e. the first dielectric layer 31a and the third dielectric layer 31c, described in the present embodiment. When the built-up structure 30 consists of odd layers more than three layers, those dielectric layers can be arranged repeatedly in the form of one dielectric layer having low Young's modulus located between two dielectric layers having high Young's modulus.

After completing the packaging substrate illustrated above, a solder mask 40 is formed on the surface of the built-up structure 30. The solder mask 40 has plural openings 41 formed by exposure and development so as to reveal the circuit layer 32c on the third dielectric layer 31c in the built-up structure 30 serving as conductive pads 321. Herein, the solder mask 40 can be made of a photosensitive polymer material having a characteristic of dewetting.

Solder materials 50 are formed on the surfaces of the conductive pads 321, which are used for conduction to outer electronic components. In the present embodiment of the present invention, the electronic components conducted with the packaging substrate can be selected from one of the group consisting of passive components, active components, optoelectronic components, and circuit boards. In the present embodiment, those are active components, and especially are semiconductor chips.

Conclusively, in the packaging substrate of the present invention, dielectric materials having Young's modulus below 1 Gpa are used as an interlayer in the built-up structure. The second dielectric layer used as the interlayer in the built-up structure of the present invention can absorb high stress resulting from mismatch of coefficient of thermal expansion so that warpage of the packaging substrate does not occur. Not only is the diameter of the conductive vias reduced, but also interfaces between the conductive vias are not cracked. Therefore, the packaging substrate having higher circuit density can be manufactured due to the conductive vias in smaller diameter.

Although the present invention has been explained in relation to its preferred embodiment, it is to be understood that many other possible modifications and variations can be made without departing from the scope of the invention as hereinafter claimed.

What is claimed is:

1. A packaging substrate structure, which at least comprises a built-up structure comprising a first dielectric layer, a second dielectric layer, and a third dielectric layer, wherein the second dielectric layer is located between the first dielectric layer and the third dielectric layer, and the packaging substrate structure is characterized in that the Young's modulus of the second dielectric layer is lower than those of the first and third dielectric layers so as to form a sandwich structure having high-low-high Young's modulus.

2. The packaging substrate structure as claimed in claim 1, wherein the Young's modulus of the second dielectric layer is below 1 Gpa.

3. The packaging substrate structure as claimed in claim 1, wherein the built-up structure further comprises plural conductive vias formed in the dielectric layers and circuit layers formed between the dielectric layers so as to conduct the circuit layer between the dielectric layers by the conductive vias.

4. The packaging substrate structure as claimed in claim 1, further comprising:
plural conductive pads formed on the surface of the built-up structure; and
a solder mask formed on the surface of the built-up structure, on which plural openings are formed to reveal the conductive pads disposed on the surface of the built-up structure.

5. The packaging substrate structure as claimed in claim 4, further comprising a solder material formed on the surfaces of the conductive pads so as to conduct outer electronic components.

6. The packaging substrate structure as claimed in claim 5, wherein the outer electronic components are selected from the group consisting of passive components, active components, optoelectronic components, and circuit boards.

7. The packaging substrate structure as claimed in claim 4, wherein the solder mask is made of a photosensitive polymer material having a characteristic of dewetting.

8. The packaging substrate structure as claimed in claim 1, wherein the first dielectric layer, the second dielectric layer, and the third dielectric layer are respectively selected from one of the group consisting of Ajinomoto Build-up film (ABF), bismaleimide triazine (BT), benzocylobutene (BCB), liquid crystal polymer (LCP), polyimide (PI), poly(phenyl ether) (PPE), poly(tetrafluoroethylene) (PTFE), aramide, epoxy resin, resin containing rubber, and glass fiber.
